(19) United States
(12) Patent Application Publication
(10) Pub. No.: US 2013/0154662 A1
(43) Pub. Date: Jun. 20, 2013

(54) TESTING SYSTEM AND METHOD FOR ELECTRONIC DEVICE

(71) Applicant: LI-WEN GUO, Shenzhen City (CN)

(72) Inventor: LI-WEN GUO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/564,791

(22) Filed: Aug. 2, 2012

(30) Foreign Application Priority Data
Dec. 16, 2011 (CN) 201110423288.X

(51) Int. Cl. G01R 31/02

(52) U.S. Cl. 324/537

(57) ABSTRACT

A testing system for testing an under test electronic device, includes a power supply status detection module, a temperature detection module, an error detection module, a storage unit, and a control terminal. The power supply status detection module detect power supply status of the under test electronic device and generates corresponding power signal. The temperature detection module detects temperature in the under test electronic device and generates corresponding temperature signal. The error detection module detects running error of the under test electronic device and generates corresponding error occurring signal. The storage unit stores the power signal, the temperature signal, and the error occurring signal. The control terminal picks out the power signal, the temperature signal, and the error occurring signal from the storage unit and analyzes these signals.

### BACKGROUND

1. Technical Field

The present disclosure relates to testing systems and methods, and more particularly to a testing system and method for testing electronic devices.

2. Description of Related Art

After an electronic device is developed, an overall test is required to check the electronic device. The test mainly aims at the requirements such as resistance at an elevated temperature, stableness of power supply, and stableness of running. However, conventional testing method can not capture detailed testing process. It is difficult to analyze and solve problems generated in the testing process.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of a testing system for testing an under test electronic device in accordance with an embodiment.

FIG. 2 illustrates a flowchart of a testing method for testing an under test electronic device in accordance with an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

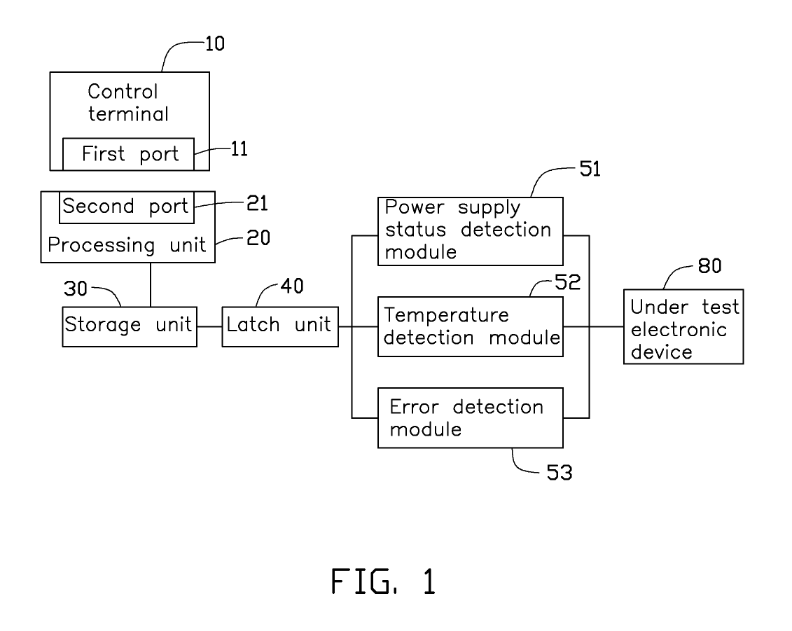

FIG. 1 shows an embodiment of a testing system for testing an under test electronic device 80. The testing system includes a control terminal 10, a processing unit 20, a storage unit 30, a latch unit 40, a power supply status detection module 51, a temperature detection module 52, and an error detection module 53.

The control terminal 10 includes a first port 11. The processing unit 20 includes a second port 21. The first port 11 and the second port 21 are same type of ports, and can connected to each other to communicate between the control terminal 10 and the processing unit 20.

The storage unit 30 is connected to the processing unit 20. The latch unit 40 is connected to the storage unit 30, the power supply status detection module 51, the temperature detection module 52, and the error detection module 53. The power supply status detection module 51, the temperature detection module 52, and the error detection module 53 are connected to the under test electronic device 80.

The power supply status detection module 51 detects power supply status of the under test electronic device 80. For example, the power supply status detection module 51 detects if an input voltage of the under test electronic device 80 is too high or too low, or detects if the input voltage is stable. The power supply status detection module 51 generates corresponding power signal according to the power supply status of the under test electronic device 80. The latch unit 40 latches the power signal.

The temperature detection module 52 detects temperature in the under test electronic device 80, and generates corresponding temperature signal. The latch unit 40 latches the temperature signal.

The error detection module 53 detects running error when the under test electronic device 80 is running, and generates corresponding error occurring signal. The latch unit 40 latches the error occurring signal.

The latch unit 40 can store the latched power signal, temperature signal, and the error occurring signal in the storage unit 30. The control terminal 10 can pick out the latched power signal, the temperature signal, and the error occurring signal from the storage unit 30 via the processing unit 20, and analyzes these latched signals. The control terminal 10 can transmit testing signals to the processing unit 20. The processing unit 20 can send the testing signals to the under test electronic device 80 to test the under test electronic device 80. The control terminal 10 can set a sampling frequency for the power supply status detection module 51, the temperature detection module 52, and the error detection module 53. The power supply status detection module 51, the temperature detection module 52, and the error detection module 53 detect the under test electronic device 80 under the sampling frequency.

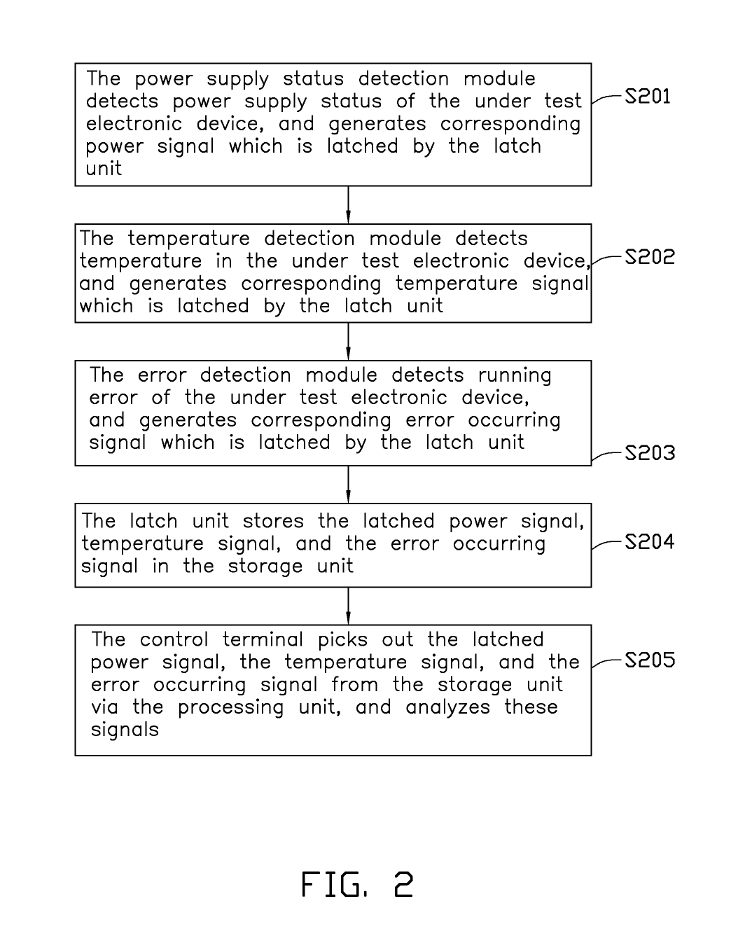

FIG. 2 shows an embodiment of a flow chart of a testing method for testing the under test electronic device 80. The testing method includes the following steps:

In step 201, the power supply status detection module 51 detects power supply status of the under test electronic device 80, and generates corresponding power signal which is latched by the latch unit 40.

In step 202, the temperature detection module 52 detects temperature of the under test electronic device 80, and generates corresponding temperature signal which is latched by the latch unit 40.

In step 203, the error detection module 53 detects running error of the under test electronic device 80, and generates corresponding error occurring signal which is latched by the latch unit 40.

In step 204, the latch unit 40 stores the latched power signal, temperature signal, and the error occurring signal in the storage unit 30.

In step 205, the control terminal 10 picks out the latched power signal, the temperature signal, and the error occurring signal from the storage unit 30 via the processing unit 20, and analyzes these signals.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A testing system for testing an under test electronic device, comprising:
a power supply status detection module configured to detect power supply status of the under test electronic device and generate a power signal;
a temperature detection module configured to detect temperature in the under test electronic device and generate a temperature signal;
an error detection module configured to detect running error of the under test electronic device and generate an error occurring signal;
a storage unit configured to store the power signal, the temperature signal, and the error occurring signal therein; and
a control terminal configured to pick out the power signal, the temperature signal, and the error occurring signal from the storage unit and analyze the power signal, the temperature signal, and the error occurring signal.

2. The testing system of claim 1, wherein a latch unit is connected to the power supply status detection module, the temperature detection module, and the error detection module, the latch unit latches the power signal, the temperature signal, and the error occurring signal therein before stored the power signal, the temperature signal, and the error occurring signal in the storage unit.

3. The testing system of claim 2, wherein a processing unit is connected between the control terminal and the storage unit, the control terminal comprises a first port, the processing unit comprises a second port, and the first port is connected to the second port to communicate the control terminal with the processing unit.

4. The testing system of claim 3, wherein the control terminal is configured transmit testing signals to the processing unit, and the processing unit is configured to test the under test electronic device.

5. The testing system of claim 3, wherein the first port and the second port are same type ports.

6. The testing system of claim 1, wherein the control terminal is configured to set a sampling frequency for the power supply status detection module, the temperature detection module, and the error detection module to detect the under test electronic device under the sampling frequency.

7. A testing method for testing an under test electronic device, comprising:
detecting power supply status of the under test electronic device and generating a power signal by an power supply status detection module;
detecting temperature in the under test electronic device and generating a temperature signal by an temperature detection module;
detecting running error of the under test electronic device and generating an error occurring signal by an error detection module;
storing the power signal, the temperature signal, and the error occurring signal in a storage unit; and
picking out the power signal, the temperature signal, and the error occurring signal from the storage unit and analyzing the power signal, the temperature signal, and the error occurring signal by a control terminal.

8. The testing method of claim 7, wherein before storing the power signal, the temperature signal, and the error occurring signal in the storage unit, a latch unit latches the power signal, the temperature signal, and the error occurring signal therein.

9. The testing method of claim 7, wherein the control terminal sets a sampling frequency for the power supply status detection module, the temperature detection module, and the error detection module to detect the under test electronic device under the sampling frequency.

10. The testing method of claim 7, wherein the step of detecting power supply status of the under test electronic device comprises detecting if an input voltage of the under test electronic device is too high or too low or stable.
